(19) United States
(12) Patent Application Publication
(10) Pub. No.: US 2026/0293036 A1
(43) Pub. Date: Sep. 24, 2026

(54) ZERO RACK UNIT PANEL

(71) Applicant: viaPhoton, Inc., Aurora, IL (US)

(72) Inventors: Yihan ZHANG, Aurora, IL (US); Jeffrey Earl JONES, SR., Stewartstown, PA (US); Mark James SMRHA, Chicago, IL (US); Walter Mark HENDRIX, Dallas, TX (US); Wade James WOMACK, Allen, TX (US)

(21) Appl. No.: 19/364,938

(22) Filed: Oct. 21, 2025

Related U.S. Application Data
(60) Provisional application No. 63/710,412, filed on Oct. 22, 2024.

(51) Int. Cl. H05K 7/18; H05K 7/14

(52) U.S. Cl. CPC H05K 7/186; H05K 7/1401; H05K 7/1491

(57) ABSTRACT

An apparatus, system, and method are provided for mounting modules to the exterior of a rack without occupying standard rack-unit space. The apparatus includes a panel configured for attachment to a stanchion of the rack, the panel comprising attachment features for securing the panel, a module bay for receiving a module, a clip for retaining the module, and a cable bar for supporting cables associated with the module. The panel is mounted to the exterior of a rack stanchion, with a module being retained in the panel outside the rack-mount space.

### CROSS-REFERENCE TO RELATED APPLICATIONS

This Application claims the benefit of U.S. Provisional Application Ser. No. 63/710,412, filed Oct. 22, 2024, which is hereby incorporated by reference for all purposes.

### BACKGROUND

Equipment racks in data centers and telecommunication rooms are used for housing various rack-mounted panels and equipment. Network equipment is installed inside the available rack spaces. data center infrastructure should be managed to optimize the use of available rack space while accommodating an increasing density of fiber connections.

As networks expand, there is a need to manage more cables and connectors within the same physical footprint, which can lead to congestion, difficult cable routing, and limited scalability. Traditional rack-mounted solutions are often constrained by the fixed number of RU slots, making it difficult to scale up without overhauling the existing infrastructure. Additionally, installation and maintenance can become cumbersome due to restricted access to connectors and cables within the rack.

### SUMMARY

Aspects of one or more embodiments provide for an apparatus in the form of a panel configured for attachment to an exterior surface of a rack. The panel includes attachment features, such as mounting holes or slots, for securing the panel to a stanchion of the rack. The panel further incorporates a module bay for receiving a module, a clip that retains the module in position, and a cable bar extending outward to support cables associated with the module. In some forms, the cable bar is reinforced by a bar support to increase structural stability during cable routing.

Aspects of one or more embodiments also provide a system in which a rack includes stanchions defining a rack-mount space, and a panel is mounted on an exterior surface of one of the stanchions. A module is inserted into a module bay of the panel and retained in position by a clip. The panel is located outside of the rack-mount space, thereby enabling modules to be secured to the rack without occupying the interior rack units. The system supports modules having front interfaces for optical connectors and provides pathways for cable management external to the rack.

Aspects of one or more embodiments further provide a method that involves attaching a panel to an exterior surface of a rack, inserting a module into a module bay of the panel, and retaining the module with a clip of the panel. The method may also include routing cables along a cable bar extending from the panel, reinforcing the cable bar with a bar support, fastening the panel to a stanchion using slotted mounting holes, and aligning the module with the bay for sliding engagement. The method may further provide for the installation of multiple modules side-by-side within the same panel to increase density while maintaining external placement.

Other aspects of one or more embodiments will be apparent from the following description and the appended claims.

### BRIEF DESCRIPTION OF DRAWINGS

FIG. 1 shows a rack in accordance with one or more embodiments.

FIGS. 2A and 2B illustrate the installation of a Zero-RU panel on a standard equipment rack in accordance with one or more embodiments.

FIG. 3 depicts a panel mounted on the exterior of a rack stanchion, in accordance with one or more illustrative embodiments.

FIG. 4 illustrates a panel for mounting on the exterior of a rack, in accordance with one or more illustrative embodiments.

FIGS. 5A and 5B show a module and panel, in accordance with one or more illustrative embodiments.

FIG. 6 is a flow diagram illustrating a process for attaching a panel to a rack, in accordance with one or more illustrative embodiments.

Like elements in the various figures are denoted by like reference numerals for consistency.

### DETAILED DESCRIPTION

Conventional rack-mounted solutions require equipment and modules to be installed within the defined rack-unit spaces located between opposing stanchions. This arrangement consumes the limited internal space of the rack, constrains scalability, and complicates cable management.

The embodiments described herein advance beyond these methods by relocating panel mounting to the exterior surfaces of rack stanchions. By attaching the panel externally, modules are positioned outside of the standard rack-mount space, preserving the interior rack units for other equipment while creating additional capacity for external module integration.

The disclosed panel incorporates a module bay formed within the panel provides a defined receiving location for a module, while a clip and optional clip lock engage the module to prevent disengagement during operation. A cable bar extends outward from the panel to support routing of optical or electrical cables associated with the module, and a bar support reinforces the cable bar to stabilize cable loading forces. These features create a coordinated structure for securely mounting modules and organizing cables in an external rack zone.

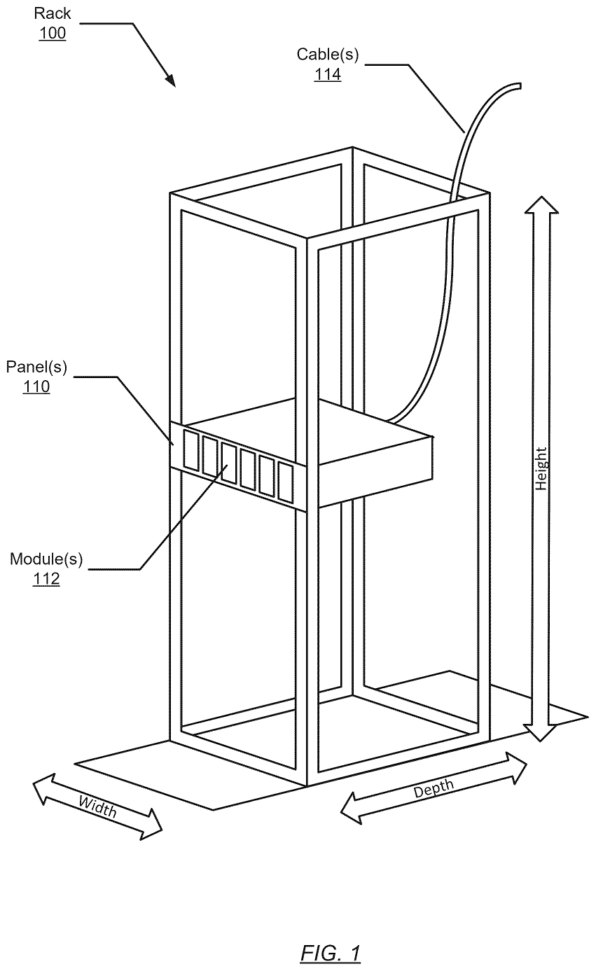

Turning to FIG. 1, a rack is shown in accordance with one or more embodiments. The rack (100) is a piece of telecommunications equipment that provides for the housing and organization of diverse telecommunication devices.

The outer dimensions of rack (100) conform with most network and server equipment. For example, rack width may measure 19 inches (48.26 cm) or 23 inches (58.42 cm) in width, standard measurements that are adhered to in the telecommunications industry. Other dimensions may be used, e.g., 21 inches, 23 inches, etc. The dimensions ensure that the rack can accommodate equipment with different form factors, such as 1 U, 2 U, or larger units, where “U” represents a standard rack unit of measure equal to 1.75 inches in height.

The rack (100) may include a series of uniformly spaced vertical mounting slots, located on both the front and rear, to facilitate the arrangement and mounting of various telecommunication devices and components. The slots serve as attachment points for mounting the panel(s) (110). The rack (100) may further be equipped with additional features such as ventilation openings and cable management.

Panel(s) (110) are components that mount within the rack (100) to organize, secure, and provide access to connective hardware. The panel may be constructed from materials such as steel or aluminum that can support the weight of the modules and withstand the physical demands of a data center environment.

Panel(s) (110) are formed with standardized form factors for compatibility with the mounting slots of the rack (100). For example, panel(s) (110) may include standardized mounting points to align with rack units, a layout that supports the intended cable or connector density, and provisions for labeling and user accessibility.

The panel(s) (110) may be equipped with one or more module(s) (112) to secure the fibers using ports, connector adapters, connectors, etc. Module(s) (112) are prefabricated units or sub-assemblies designed for quick installation into the rack (100). The module(s) (112) may include electronic components and/or optical components, such as optical connectors, optical fibers, switches, routers, or patches. The module(s) (112) may include features for splicing, cable management, and security.

Each module(s) (112) is designed to contain a specific number of optical connectors, optimizing space utilization within the rack mount to support high fiber densities. For example, each module(s) (112) may support fiber densities of 144 fibers, 288 fibers, and/or 576 fibers per module, as well as other suitable densities. The connectors may be an industry-standard connector such as a standard connector (SC), Lucent connector (LC), or Multi-fiber Termination Push-on connector (MTP), depending on the network requirements.

The module(s) (112) may have multiple widths, such that a varying number of modules may be housed within the panel(s) (110). The module(s) (112) may be sized to fit twelve (12) modules in the panel(s) (110), however other sizes—e.g., 2, 3, 4, 6, 8—are also contemplated. When fully loaded with module(s) (112), the panel(s) (110) support fiber densities of 1728 fibers, 3456, fibers, and/or 6912 fibers per panel, as well as other suitable densities.

Cable(s) (114) may be fiber optic cables that carry data signals between different network devices and components. Cable(s) (114) are routed through the data center infrastructure, connecting panels, modules, and external devices. For example, cable(s) (114) may interconnect module(s) (112). Cable(s) (114) may include a core, cladding, and protective coating, which ensure the integrity of the data signal. Cable(s) (114) can be single-mode or multi-mode, depending on the network requirements. Cable(s) (114) may be color-coded to facilitate identification during installation and maintenance.

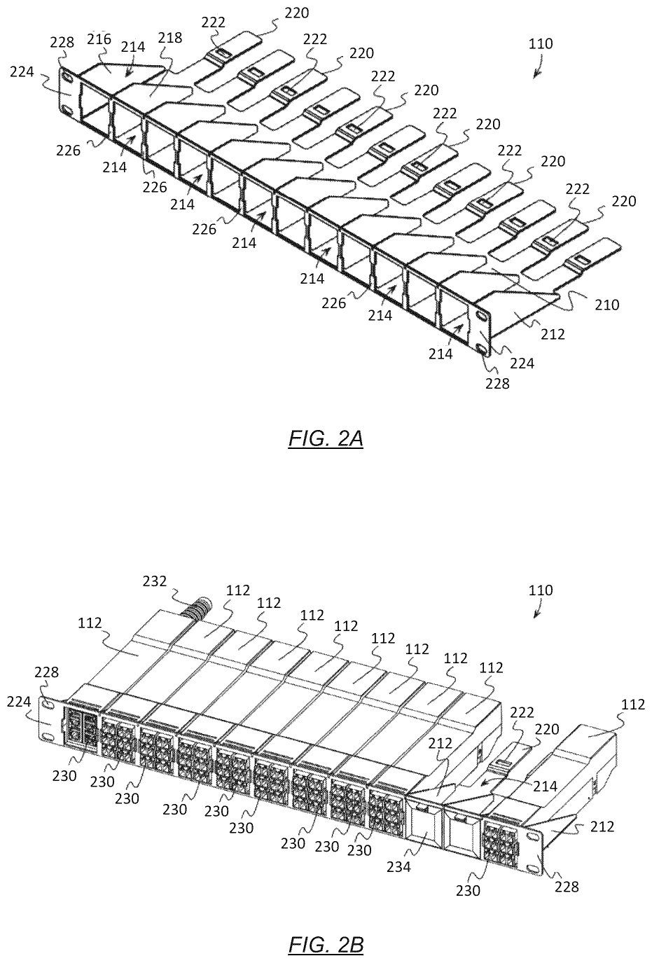

FIGS. 2A and 2B illustrate an example of a panel equipped with one or more modules, according to various embodiments. The panel and modules are panel(s) (110) and module(s) (112) of FIG. 1.

The panel(s) (110) may comprise a frame base (210) to which two or more dividers (212) may be coupled. Preferably, the frame base (210) and the dividers (212) may each be generally planar or flat in shape. The dividers (212) may be oriented generally perpendicular to the frame base (210). Optionally, two or more of the dividers (212) may be oriented generally parallel to each other, and preferably each of the dividers (212) of a panel(s) (110) may be oriented generally parallel to each other. The elements of the panel(s) (110) may be made from or may comprise durable materials such as various types of stamped sheet metal, plastics, carbon fiber, or any other generally rigid material.

An alignment slot (214) may be formed and bounded by two adjacent dividers (212), such as a first divider (216) and a second divider (218), and by portions of the frame base (210) extending between the two adjacent dividers (212). For example, thirteen dividers (212) may be coupled to a frame base (210) to form twelve alignment slot (214). In some embodiments, a first divider (216) and second divider (218) may be separated by a distance that is slightly greater than the width of the module(s) (112) so that the module(s) (112) may be snugly or received in the alignment slot (214) between the two adjacent dividers (212).

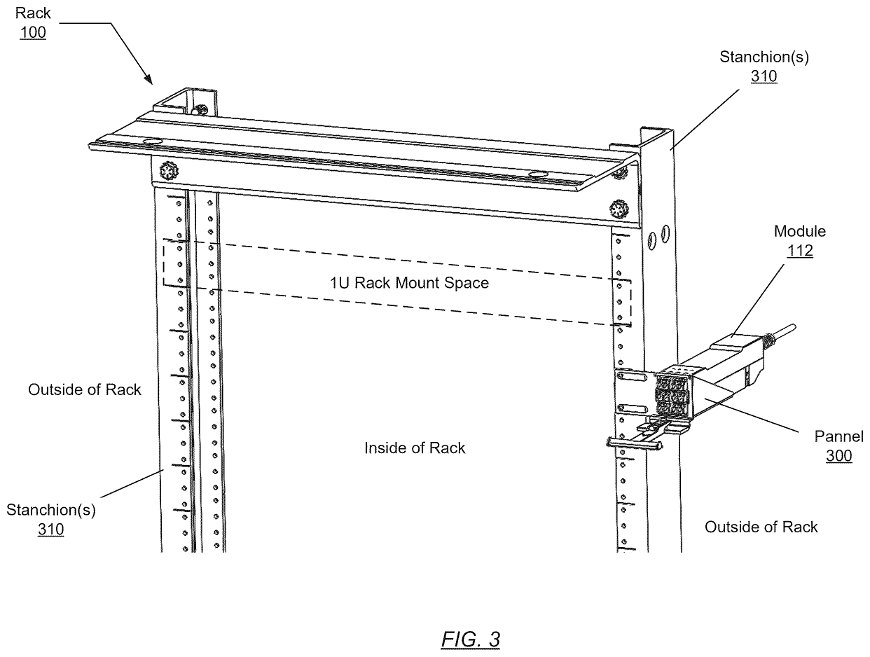

The dividers (212) may be configured in any shape and size. In some embodiments, one or more of the dividers (212) may be configured with a generally triangular shape. In preferred embodiments, one or more of the dividers (212) may comprise a generally right trapezoid shape having two adjacent right angles and two parallel sides as shown in FIGS. 3A and 3C. In other embodiments, one or more of the dividers (212) may comprise a generally square shape, half circle shape, rectangular shape, or any other shape.

The panel(s) (110) may comprise one or more key(s) (220) which may be coupled to, optionally by being integrally formed with, the frame base (210). In some embodiments, a key(s) (220) may be coupled to a frame base (210) so that the key(s) (220) may extend away from an alignment slot (214) of the panel(s) (110). In preferred embodiments, each key(s) (220) may be coupled to a frame base (210) so that each key(s) (220) may extend away from a respective alignment slot (214) of the panel(s) (110). In further preferred embodiments, the panel(s) (110) may comprise a key(s) (220) extending away from each alignment slot (214).

Each key(s) (220) may comprise a key aperture (222) which may be positioned anywhere on the key(s) (220). In some embodiments, all or portions of a key(s) (220) may be movable relative to the frame base (210). In preferred embodiments, the portion of the key(s) (220) having the key aperture (222) may be movable relative to the frame base (210). Optionally, the key(s) (220) and/or frame base (210) may be made from a flexible material, such as a sheet of plastic or metal, which may allow the portion of the key(s) (220) having the key aperture (222) to be movable relative to the frame base (210). In other embodiments, any movable coupling may be used to enable the portion of the key(s) (220) having the key aperture (222) to be movable relative to the frame base (210), such as any type of hinge or movable fastener. By being movable, the key aperture (222) may be moved into and out of contact with a lock tab of a module(s) (112) that is received in a respective alignment slot (214).

In some embodiments, the panel(s) (110) may comprise a face plate (224) which may be coupled to one or more dividers (212), frame base (210), or other element of the panel(s) (110). A face plate (224) may comprise a number of gate(s) (226), in which each gate(s) (226) may form and bound the entrance of an alignment slot (214) opposite the key(s) (220) of the alignment slot (214). In some embodiments, a face plate (224) may comprise one or more, and preferably four securement aperture(s) (228) which may be sized and shaped to receive one or more fasteners, such as screws, bolts, other threaded fasteners, or any other type of fastener, which may be used to secure the panel(s) (110) to rack (100) of FIG. 1.

Each alignment slot (214) may be configured to received one or more module(s) (112). In some embodiments, a module(s) (112) may be secured or coupled to the panel(s) (110) via engagement with a key aperture (222). For example, a module(s) (112) may be secured or coupled to the panel(s) (110) via engagement between a lock tab on the module(s) (112) with a key aperture (222) of a key (220).

The module(s) (112) may secure one or more cables to their respective cable coupling(s) (230) and/or strain relief (232). In some embodiments, a blanking plug (234) may be coupled to module(s) (112) to prevent dirt, contaminants, unwanted access, etc. the module(s) (112) and any cable connectors (230) positioned in the module(s) (112).

FIG. 3 depicts the relationship of a panel (300) to a rack (100) and its stanchions (310), illustrating how the panel is positioned relative to the inside and outside of the rack. The rack (100) provides the structural frame that defines a rack-mount space used for housing standard equipment. The stanchions (310) form the vertical boundaries of this space and serve as attachment points for both internal and external components. The panel (300) is mounted to an exterior surface of one of the stanchions (310), establishing its placement outside of the conventional rack-mount space.

The panel (300) extends into the region identified as the outside of the rack. This orientation separates the panel from the equipment and modules that are mounted within the inside of the rack, which is bounded between opposing stanchions (310). By locating the panel (300) externally, the rack interior remains available for conventional components, while the panel supports additional functionality in the external zone.

A module (112) is shown supported by the panel (300). The module projects outwardly from the rack into the outside region, demonstrating how functional elements can be installed externally while still being mechanically secured to the rack structure. This placement allows modules to be physically separated from equipment mounted inside the rack while maintaining accessibility for connection and routing.

The inside of the rack is designated in contrast to the outside region where the panel (300) is positioned. The inside accommodates traditional rack-mounted devices that occupy standardized rack-unit spaces. The outside region, by comparison, is beyond the plane of the stanchions (310), providing an additional surface where the panel and module may be supported without using interior rack space. This arrangement defines two distinct zones of equipment placement while using a common rack framework.

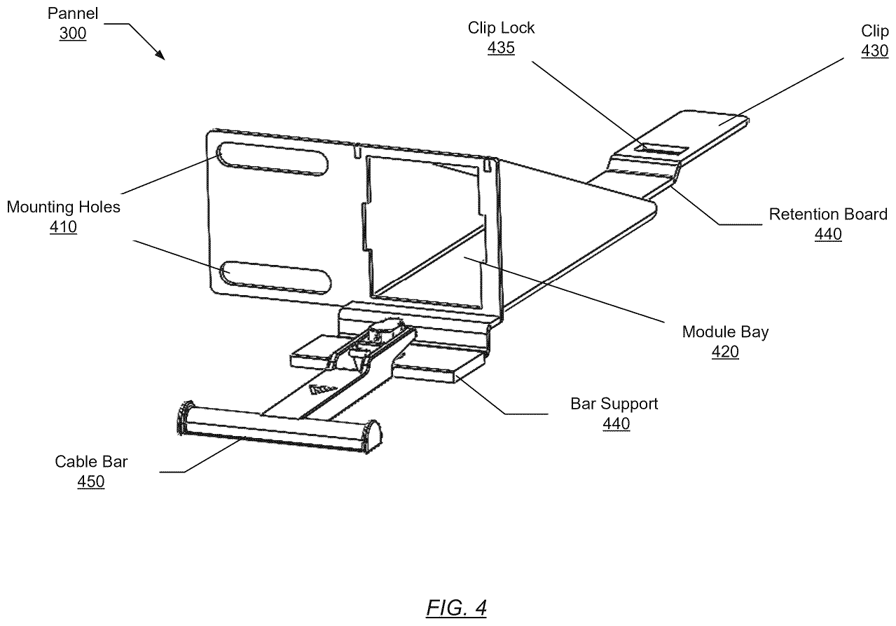

FIG. 4 shows the structure of a panel (300) and the arrangement of components that enable attachment to a rack, support of a module, and routing of cables. The panel (300) is illustrated with multiple elements that interact to secure and organize the modules mounted externally to a stanchion of the rack. Each structural feature is positioned relative to the others to form a functional assembly.

Mounting holes (410) are provided along the body of the panel (300). These openings serve as attachment features for receiving fasteners that connect the panel to a stanchion of the rack. The mounting holes (410) are arranged to permit alignment of the panel and to provide stable engagement with the rack structure. In some forms, the holes may be slotted to allow for vertical or horizontal adjustment during installation.

The module bay (420) is integrated into the panel (300) and is configured to receive a module. The module bay defines a recess or cavity in which the module can be positioned and held in place. This bay provides the structural framework into which additional retaining elements operate to stabilize the module once inserted.

A clip (430) is positioned along the edge of the module bay (420). The clip (430) engages with the module to hold it within the bay. The clip is accompanied by a clip lock (435), which is configured to secure the clip in its engaged position once the module is inserted. Together, these features prevent unintended release of the module and maintain its seated orientation.

A retention board (440) is located within the module bay (420). The retention board provides added structural support for the module and distributes mechanical loads associated with insertion and retention. The retention board operates in coordination with the clip (430) and clip lock (435) to stabilize the module along multiple surfaces of the bay.

The cable bar (450) extends outward from the panel (300). This component provides a pathway for organizing and routing cables associated with the module, ensuring that the cables are supported externally rather than intruding into the rack interior. The cable bar is positioned to align with the front of the module, enabling cables to be directed away from the rack structure.

A bar support (440) is associated with the cable bar (450). The bar support extends from the module bay and reinforces the mechanical stability of the cable bar. This structural relationship ensures that forces applied to the cable bar during cable routing are transferred to the panel body, reducing stress on the connection points.

The relative arrangement of the mounting holes (410), module bay (420), clip (430), clip lock (435), retention board (440), cable bar (450), and bar support (440) provides a coordinated assembly for external module mounting. Each element interacts with the others to secure the panel to the rack, retain the module, and manage cables in an organized manner outside of the rack interior.

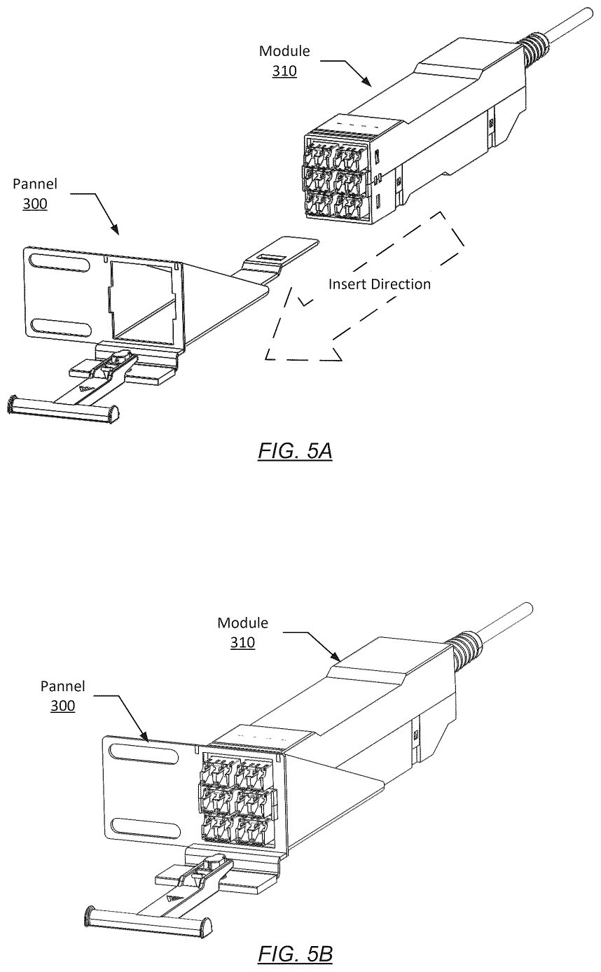

FIGS. 5A and 5B illustrate the process of inserting a module (310) into a panel (300). These figures demonstrate the relative positioning of the module and panel prior to and during engagement, as well as the interaction of the components during installation.

In FIG. 5A, the module (310) is aligned with the panel (300) along an insertion direction indicated by the arrow. The module is positioned forward of the module bay of the panel and is oriented for movement into the bay. This alignment step ensures that the edges and interfaces of the module correspond to the receiving features of the panel before insertion proceeds.

FIG. 5B depicts the module (310) after partial or full insertion into the panel (300). The module is guided along the insertion direction into the module bay defined in the panel. As the module moves into place, it engages with clips and other retaining structures of the panel, which secure the module against displacement once fully seated.

The sequence shown across FIGS. 5A and 5B demonstrates how modules are introduced into the panel externally to the rack. The insertion action positions the module in mechanical engagement with the panel features, including the clip and clip lock, while leaving the module accessible from the outside of the rack. This configuration enables secure installation without occupying the rack's interior rack-unit space.

Cables associated with the module, although not explicitly shown in these figures, may be routed after insertion using the cable bar that extends from the panel. The alignment and engagement shown in FIGS. 5A and 5B provide the structural basis for retaining modules while supporting subsequent cable management.

FIG. 2 illustrates the installation of a Zero-RU panel on a standard equipment rack in accordance with one or more embodiments. The rack (100) includes vertical stanchions (210), which define the typical rack-mount space used for housing equipment modules between them.

The Zero-RU panel (200) is mounted on the exterior side of the stanchions, outside the traditional rack-mount space. This positioning allows the panel to utilize the unused external areas along the sides of the rack (100) without occupying any standard rack units (RU) within the rack (100).

The Zero-RU panel (200) is configured to accommodate one or more modules (220) which can be secured within the Zero-RU panel (200). The modules extend outward from the rack, providing flexibility in expanding fiber connections or adding other components without interfering with existing equipment inside the rack.

FIG. 3 depicts the structure of the Zero-RU panel (200) in accordance with one or more embodiments. The panel includes mounting holes, identified as element 310, which are positioned to allow for adjustable alignment during installation on a rack. These slots facilitate secure attachment to the rack stanchions and accommodate variations in positioning.

The central part of the panel is a module bay (320), designed to hold modules securely within the panel. Clip (330) helps to retain and stabilize the installed modules.

The panel may be equipped with equipped with a cable bar (340) extending from the lower part of the assembly. This bar provides for organizing and routing cables associated with the installed modules.

Referring now to FIGS. 4A and 4B, the process of installing a module, into the Zero-RU panel is shown in accordance with one or more embodiments. In FIG. 4A, the module positioned in alignment with the panel, prepared for insertion. The module is oriented to slide into the module bay of the Zero-RU panel, aligning with the panel's structure for a secure fit.

In FIG. 4B, the module is shown fully inserted and engaged with the Zero-RU panel. The module is securely seated within the module bay, with the clip mechanism ensuring its retention.

FIGS. 5A and 5B illustrate the process of inserting a module (310) into a panel (300). These figures demonstrate the relative positioning of the module and panel prior to and during engagement, as well as the interaction of the components during installation.

In FIG. 5A, the module (310) is aligned with the panel (300) along an insertion direction indicated by the arrow. The module is positioned forward of the module bay of the panel and is oriented for movement into the bay. This alignment step ensures that the edges and interfaces of the module correspond to the receiving features of the panel before insertion proceeds.

FIG. 5B depicts the module (310) after partial or full insertion into the panel (300). The module is guided along the insertion direction into the module bay defined in the panel. As the module moves into place, it engages with clips and other retaining structures of the panel, which secure the module against displacement once fully seated.

The sequence shown across FIGS. 5A and 5B demonstrates how modules are introduced into the panel externally to the rack. The insertion action positions the module in mechanical engagement with the panel features, including the clip and clip lock, while leaving the module accessible from the outside of the rack. This configuration enables secure installation without occupying the rack's interior rack-unit space.

Cables associated with the module, although not explicitly shown in these figures, may be routed after insertion using the cable bar that extends from the panel. The alignment and engagement shown in FIGS. 5A and 5B provide the structural basis for retaining modules while supporting subsequent cable management.

While FIGS. 1-5 show a configuration of components, other configurations may be used without departing from the scope of one or more embodiments. For example, various components may be combined to create a single component. As another example, the functionality performed by a single component may be performed by two or more components.

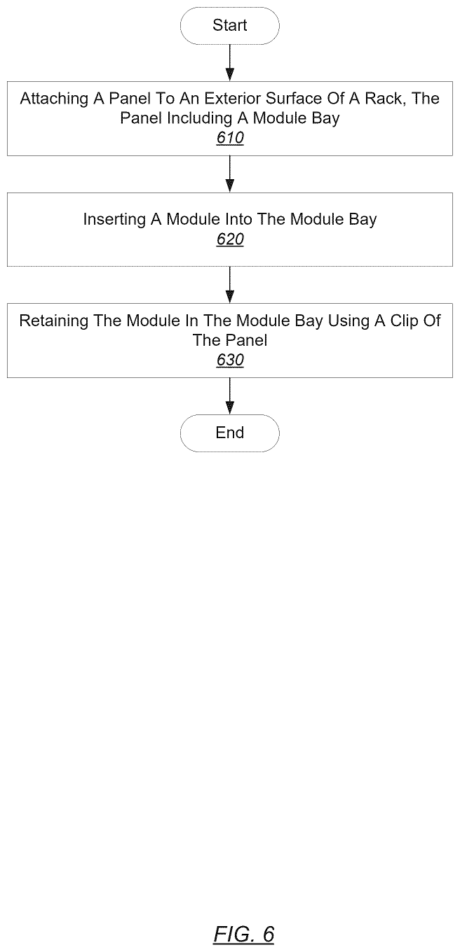

FIG. 6 depicts a flow diagram showing the sequential operations for mounting a panel to a rack, installing a module, and organizing associated cables. Each step is represented as part of a process that results in a module being secured externally to the rack structure.

Step (610) illustrates attaching a panel to an exterior surface of a rack, where the panel includes a module bay. The attachment may involve fastening the panel to a stanchion of the rack using attachment features, such as slotted mounting holes, that permit alignment and adjustment during installation.

Step (620) shows inserting a module into the module bay of the panel. The module is positioned in alignment with the bay and advanced along an insertion direction until seated within the panel. This action places the module in position for engagement with retaining structures.

Step (630) represents retaining the module in the module bay using a clip of the panel. The clip engages the module to hold it in place and may operate with additional elements, such as a clip lock or a bar support, to stabilize the assembly.

Following retention, the process may include routing one or more cables along a cable bar extending from the panel. The cable bar organizes and supports the cables in a defined pathway outside the rack interior.

The process may further include securing the cable bar to a bar support extending from the module bay. This reinforcement transfers forces applied to the cable bar into the panel body, maintaining stability during cable management.

In some implementations, attaching the panel involves positioning the slotted mounting holes relative to the rack stanchion and fastening the panel in an adjusted orientation. This attachment allows for precise alignment of the panel on the rack.

The insertion step may also include guiding the module along the insertion direction and sliding it into engagement with the clip. In some embodiments, the rack may be sized to allow multiple modules may be arranged side-by-side within the same panel to increase capacity, with each module being retained and supported by the panel structure.

As used herein, the term “connected to” contemplates multiple meanings. A connection may be direct or indirect (e.g., through another component or network). A connection may be wired or wireless. A connection may be a temporary, permanent, or semi-permanent communication channel between two entities.

The various descriptions of the figures may be combined and may include or be included within the features described in the other figures of the application. The various elements, systems, components, and steps shown in the figures may be omitted, repeated, combined, or altered as shown in the figures. Accordingly, the scope of the present disclosure should not be considered limited to the specific arrangements shown in the figures.

In the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, ordinal numbers distinguish between the elements. By way of an example, a first element is distinct from a second element, and the first element may encompass more than one element and succeed (or precede) the second element in an ordering of elements.

Further, unless expressly stated otherwise, the conjunction “or” is an inclusive “or” and, as such, automatically includes the conjunction “and,” unless expressly stated otherwise. Further, items joined by the conjunction “or” may include any combination of the items with any number of each item, unless expressly stated otherwise.

In the above description, numerous specific details are set forth in order to provide a more thorough understanding of the disclosure. However, it will be apparent to one of ordinary skill in the art that the technology may be practiced without these specific details. In other instances, well-known features have not been described in detail to avoid unnecessarily complicating the description. Further, other embodiments not explicitly described above can be devised which do not depart from the scope of the claims as disclosed herein. Accordingly, the scope should be limited only by the attached claims.

What is claimed is:

1. An apparatus comprising:
a panel configured for attachment to an exterior surface of a rack, wherein the panel comprises one or more attachment features configured to secure the panel to a single stanchion of the rack.

2. The apparatus of claim 1, wherein the panel is configured to be mounted outside of a standard 1 rack-unit space of the rack.

3. The apparatus of claim 1, wherein the one or more mounting holes comprises slotted mounting holes configured to permit adjustable alignment of the panel on the rack.

4. The apparatus of claim 1, the wherein the panel comprises:
a module bay;
a clip configured to retain a module within the module bay; and
a cable bar extending from the panel and configured to support one or more cables associated with the module.

5. The apparatus of claim 4, wherein the cable bar comprises:
a T-handle configuration configured to route or organize the one or more cables.

6. The apparatus of claim 4, further comprising:
a bar support extending from the module bay and configured to provide additional support for the cable bar.

7. The apparatus of claim 4, wherein the clip comprises a spring element configured to releasably engage the module.

8. A system comprising:
a rack including a pair of stanchions defining a rack-mount space;
a panel mounted on an exterior surface of one of the stanchions, the panel including a module bay; and
a module inserted into the module bay and retained by a clip of the panel, wherein the panel is positioned outside the rack-mount space.

9. The system of claim 8, wherein the rack comprises a 19-inch or 23-inch standardized rack.

10. The system of claim 9, wherein the module includes a front interface configured to receive a plurality of fiber optic connectors.

11. The system of claim 9, wherein the panel includes a cable bar extending from a front portion of the panel for cable routing.

12. The system of claim 9, wherein the panel includes slotted mounting holes configured to permit vertical adjustment of the panel along the stanchion.

13. The system of claim 9, wherein the module comprises a fiber management module having connector adapters, splice trays, or both.

14. The system of claim 9, wherein the panel is configured to accommodate a plurality of modules arranged in parallel.

15. A method comprising:
attaching a panel to an exterior surface of a rack, the panel including a module bay;
inserting a module into the module bay; and
retaining the module in the module bay using a clip of the panel.

16. The method of claim 15, further comprising:
routing one or more cables along a cable bar extending from the panel.

17. The method of claim 15, further comprising:
securing the cable bar to a bar support extending from the module bay.

18. The method of claim 15, wherein attaching the panel comprises:
fastening the panel to a stanchion of the rack using slotted mounting holes.

19. The method of claim 15, wherein inserting the module comprises:
aligning the module with the module bay and sliding the module into engagement with the clip.

20. The method of claim 15, further comprising:
installing a plurality of modules side-by-side within the panel.
